(19) United States
(12) Patent Application Publication
(10) Pub. No.: US 2014/0284028 A1
(43) Pub. Date: Sep. 25, 2014

(54) COOLER

(71) Applicant: Toyota Jidosha Kabushiki Kaisha, Toyota-shi Aichi-ken (JP)

(72) Inventor: Tadafumi Yoshida, Kasugai-shi Aichi-ken (JP)

(73) Assignee: Toyota Jidosha Kabushiki Kaisha, Toyota-shi Aichi-ken (JP)

(21) Appl. No.: 14/222,110

(22) Filed: Mar. 21, 2014

(30) Foreign Application Priority Data
Mar. 22, 2013 (JP) 2013-059856

(51) Int. Cl. H05K 7/20

(52) U.S. Cl. CPC H05K 7/20263
USPC 165/104.19

(57) ABSTRACT

A cooler is disposed in contact with an electronic component to cool the electronic component. The cooler includes a flow passage for a cooling medium, a heat transfer portion, and a non-conductive portion. The flow passage is provided in the cooler. The heat transfer portion is in contact with the electronic component and contacts the cooling medium that flows through the flow passage. The non-conductive portion is provided in the heat transfer portion.

### INCORPORATION BY REFERENCE

The disclosure of Japanese Patent Application No. 2013-059856 filed on Mar. 22, 2013 including the specification, drawings and abstract is incorporated herein by reference in its entirety.

### BACKGROUND OF THE INVENTION

1. Field of the Invention

The present invention relates to a cooler that is used to cool an electronic component.

2. Description of Related Art

An electric power converter is known that includes a semiconductor module, a cooler that is in contact with the semiconductor module to cool the semiconductor module, and a plate spring that presses the semiconductor module into close contact with the cooler (refer to Japanese Patent Application Publication No. 2012-80027 (JP 2012-80027 A), for example). In this electric power converter, the plate spring is brought into face-to-face contact with the semiconductor module to generate a magnetic flux around the power terminal of the semiconductor module. Then, the overcurrent that is generated in the plate spring is increased by the magnetic flux. In this way, the inductance in the semiconductor module is reduced in the electric power converter.

An electric power converter is also known that includes a reactor that has a coil which generates a magnetic flux when electrified and a core that is made of a magnetic powder-mixed resin, a semiconductor module that incorporates a semiconductor device, and a cooler that cools the semiconductor module (refer to Japanese Patent Application Publication No. 2008-198981 (JP 2008-198981 A), for example). In this electric power converter, the reactor is supported among a plurality of cooling tubes that constitutes the cooler. In this way, the reactor is fixed in the case of the electric power converter and the cooling efficiency of the reactor is improved in this electric power converter.

A circuit board assembly is also known that includes a circuit board, a module and a planar coil element (refer to Japanese Patent Application Publication No. 2004-273937 (JP 2004-273937 A), for example). The module has an electronic circuit device and a radiator that is attached to the electronic circuit device, and is mounted on the circuit board. In this circuit board assembly, an extended portion that protrudes from the electronic circuit device and extends parallel to a surface of the board is formed on the radiator. The distance between the extended portion of the radiator and the planar coil element is set to such a distance that no overcurrent is generated in the extended portion by the magnetic field that is generated by the planar coil element.

### SUMMARY OF THE INVENTION

When a cooler is disposed in contact with an electronic component as described in JP 2012-80027 A, the overcurrent that is generated in the vicinity of the cooler is increased by the magnetic flux that is generated around (leaks from) the electronic component. Thus, when a cooler is disposed in contact with an electronic component, such as a reactor or capacitor, magnetic field lines are cancelled by the overcurrent that is generated in the vicinity of the cooler. When magnetic field lines are cancelled as described above, the loss in the reactor or the like, i.e., the overcurrent loss, increases.

It is, therefore, an object of the present invention to provide a cooler that can prevent an increase of loss in an electronic component and can cool the electronic component efficiently.

According to a first aspect of the present invention, a cooler is disposed in contact with an electronic component. The cooler includes a flow passage for a cooling medium, a heat transfer portion, and a non-conductive portion. The flow passage is provided in the cooler. The heat transfer portion is in contact with the electronic component and contacts the cooling medium that flows through the flow passage. The non-conductive portion is provided in the heat transfer portion.

The cooler has a flow passage for a cooling medium therein and is disposed in contact with an electronic component. The cooler can exchange heat between the electronic component and the cooling medium in the flow passage via the heat transfer portion to cool the electronic component efficiently. A non-conductive portion is provided in the heat transfer portion of the cooler. The non-conductive portion can block or interrupt the flow of overcurrent that is caused by a magnetic flux that is generated around (leaks from) the electronic component. Thus, the overcurrent that is generated in the vicinity of the cooler can be reduced to prevent an increase of loss (overcurrent loss) in the electronic component. Thus, the cooler can prevent an increase of loss in an electronic component and cool the electronic component efficiently.

The cooler may include a first portion that includes the heat transfer portion, and a second portion that is fixed to the first portion and defines the flow passage in conjunction with the first portion. The heat transfer portion of the first portion may have an opening, and the non-conductive portion may be constituted of a non-conductive member that is disposed in the opening. In this case, a non-conductive portion can be easily provided in the heat transfer portion of the first portion. The non-conductive member may be liquid-tightly joined to the heat transfer portion of the first portion, and a seal member may be provided between the non-conductive member and the first portion.

In addition, the second portion may have a wall portion that is opposed to the heat transfer portion of the first portion, and at least one first protrusion that protrudes from the wall portion toward the heat transfer portion and is in contact with the non-conductive member. In this case, when the non-conductive member is assembled to the heat transfer portion of the first portion, the protrusion (first protrusion) of the second portion can support the non-conductive member. Thus, the non-conductive member can be liquid-tightly joined to the first portion with ease.

The non-conductive member may have at least one second protrusion. The second protrusion protrudes toward a wall portion of the second portion that is opposed to the heat transfer portion of the first portion and is in contact with the wall portion. In this case, when the non-conductive member is assembled to the heat transfer portion of the first portion, the wall portion of the second portion can support the second protrusion, i.e., the non-conductive member. Thus, the non-conductive member can be liquid-tightly joined to the first portion with ease.

In addition, the second portion may have a plurality of the first protrusions. The non-conductive member may have a plurality of the second protrusions. The first protrusions and the second protrusions may be arranged at intervals along the opening. In this case, the second portion can stably support the non-conductive member via the protrusions without disrupting the flow of the cooling medium through the flow passage.

The electronic component may be a reactor. In other words, according to the above aspect, the cooler can prevent an increase of loss in the electronic component by reducing overcurrent that is generated in the vicinity of the cooler by a magnetic flux that is generated around the electronic component. Thus, the cooler is very useful for cooling an electronic component in which loss is increased by overcurrent, such as a reactor.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is an exploded perspective view that illustrates a cooler according to one embodiment of the present invention;

FIG. 2 is a cross-sectional view that illustrates the cooler of FIG. 1;

FIG. 3 is a cross-sectional view that illustrates the cooler of FIG. 1;

FIG. 4 is a schematic diagram that is used to explain the function of a non-conductive portion that is provided in a heat transfer portion of the cooler of FIG. 1;

FIG. 5 is an explanatory view that illustrates a modification of the non-conductive portion that is provided in a heat transfer portion;

FIG. 6 is a schematic diagram that illustrates a modification of a non-conductive member;

FIG. 7 is a schematic diagram that illustrates an example of the manner of use of the cooler according to the present invention; and

FIG. 8 is a cross-sectional view that illustrates an example of the manner of use of the cooler according to the present invention.

### DETAILED DESCRIPTION OF EMBODIMENTS

Description is hereinafter made of a mode for carrying out the present invention with reference to the drawings.

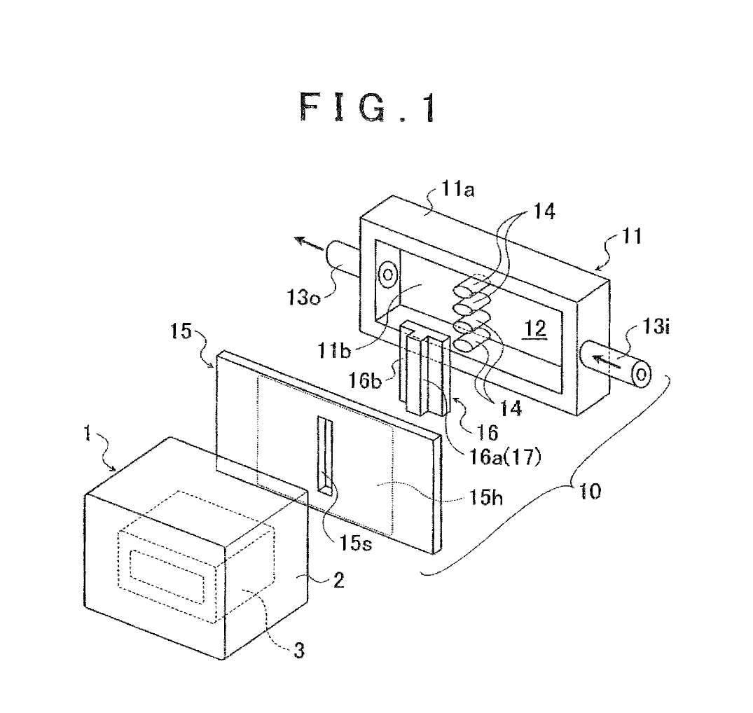

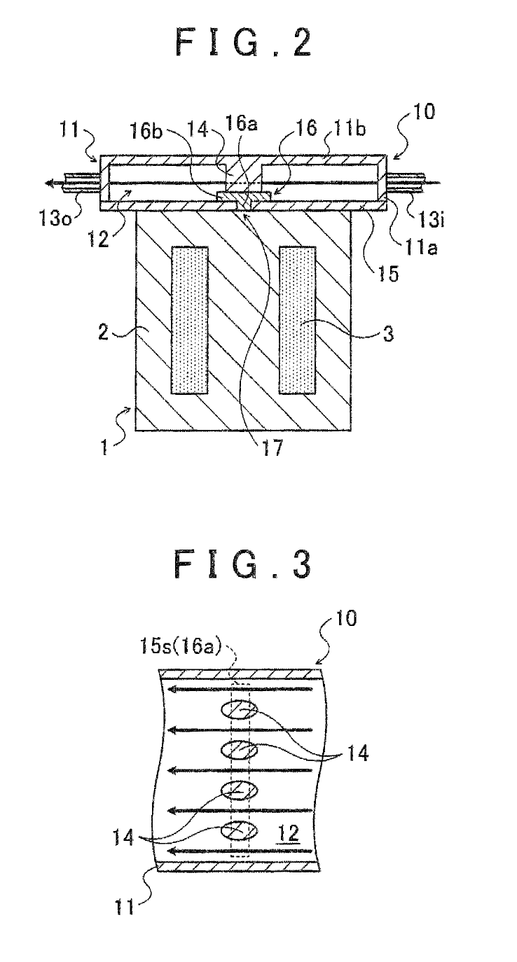

FIG. 1 is an exploded perspective view that illustrates a cooler 10 according to one embodiment of the present invention. FIG. 2 is a cross-sectional view that illustrates the cooler 10. The cooler 10 that are shown in these drawings is used to cool a reactor 1 that is mounted on a hybrid vehicle or electrical vehicle, for example. The reactor 1 is an electronic component that constitutes a boost converter that is mounted on a hybrid vehicle or electrical vehicle. The reactor 1 as an electronic component has a core 2 that is made of a magnetic material, and a coil 3 that is wound in the core 2. The core 2 is formed of a magnetic material, such as a magnetic powder-mixed resin, that is filled in the inside of the coil 3 and surrounds the outer periphery of the core 2. The reactor 1 forms a magnetic flux when the coil 3 is electrified.

As shown in FIG. 1 and FIG, 2, the cooler 10 includes a cooler body (second portion) 11, and a cooling plate 15 (first portion) that is liquid-tightly fixed (joined) to the cooler body 11. In this embodiment, the cooler body 11 is made of, for example, a metal that has a high thermal conductivity, such as copper or aluminum, or a resin that has a high thermal conductivity. The cooler body 11 has a frame portion 11a that has a rectangular flame-like configuration, and a wall portion 11b that covers the frame portion 11a from one side. The cooling plate 15 is disposed opposed to the wall portion 11b and liquid-tightly fixed to the cooler body 11 to cover an opening of the cooler body 11. In this way, a flow passage 12 for cooling water is defined by the cooler body 11, which includes the frame portion 11a and the wall portion 11b, and the cooling plate 15. The cooler body 11 may be constructed by integrally forming the frame portion 11a and the wall portion 11b. Alternatively, the cooler body 11 may be constructed by liquid-tightly fixing (joining) a separate plate body to the frame portion 11a.

A cooling medium supply pipe 13i is liquid-tightly connected to one longitudinal end of the cooler 10 for communication with the flow passage 12. A cooling medium discharge pipe 13o is liquid-tightly connected to the other longitudinal end of the cooler 10 for communication with the flow passage 12. In other words, the cooling medium supply pipe 13i is connected to one longitudinal end of the frame portion 11a of the cooler body 11, and the cooling medium discharge pipe 13o is connected to the other longitudinal end of the frame portion 11a. Cooling water (cooling medium) that is supplied from a water pump is supplied via a radiator to the cooling medium supply pipe 13i. The water pump sucks and delivers cooling water (coolant) in a reserve tank. The illustration of the water pump, the reserve tank and the radiator is omitted. The cooling water flows through the flow passage 12 into the cooling medium discharge pipe 13o, and is returned to the reserve tank through the cooling medium discharge pipe 13o.

The cooling plate 15 is made of a metal (such as copper or aluminum) or a resin that has a high thermal conductivity. The cooling plate 15 is formed to have the same shape as the wall portion 11b of the cooler body 11. The cooling plate 15 has a heat transfer portion 15h at a central portion in the longitudinal direction thereof. The heat transfer portion 15h is a portion of the cooling plate 15 which is in contact with one surface of the core 2 of the reactor 1 and which is located opposed to the flow passage 12 and contacts the cooling water. The cooler 10 is fixed to the reactor 1 with a clamp (not shown) such that the heat transfer portion 15h of the cooling plate 15 is in contact with one surface of the core 2. Alternatively, the cooler 10 is pressed against the reactor 1 by pressing means, such as a plate spring. While the cooler body 11 is made of a material that has a high thermal conductivity as in the case of the cooling plate 15 in this embodiment, only the cooling plate 15 may be made of a material that has a high thermal conductivity. In other words, the cooler body 11 is not necessarily made of a material that has a high thermal conductivity, such as copper or aluminum.

As shown in FIG. 1, a rectangular slit (opening) 15s is formed through the heat transfer portion 15h of the cooling plate 15. The rectangular slit (opening) 15s is formed to extend upward and downward in the drawing from the center of the heat transfer portion 15h, which corresponds to the center of the coil 3 of the reactor 1. An insertion portion 16a of a non-conductive member 16 that is made of, for example, a non-conductive resin is inserted into the slit 15s of the cooling plate 15. As illustrated, the non-conductive member 16 has an insertion portion 16a, and a base portion 16b, The insertion portion 16a is formed to fit tightly in the slit 15s. The base portion 16b is formed integrally with the insertion portion 16a so as to be in contact with an inner surface of the cooling plate 15, which is located opposed to the wall portion 11b.

As shown in FIG. 1 and FIG. 2, the cooler body 11 has a plurality of protrusions 14 (first protrusions). The protrusions 14 protrude from an inner surface of the wall portion 11b toward the cooling plate 15 and support the base portion 16b of the non-conductive member 16. As shown in FIG. 3, the protrusions 14 are arranged at spaced locations (at regular intervals) along the longitudinal direction of the slit 15s (the insertion portion 16a) of the cooling plate 15. In this embodiment, the insertion portion 16a is inserted into the slit 15s with the front side of the base portion 16b in contact with an inner surface of the cooling plate 15 and the back side of the base portion 16b in contact with the protrusions 14 of the cooler body 11. The non-conductive member 16 is heated with the insertion portion 16a and the base portion 16b in the above state. The insertion portion 16a is thereby liquid-tightly joined (welded and fixed) to the inner walls of the slit 15s, and the base portion 16b is liquid-tightly joined (welded and fixed) to an inner surface of the cooling plate 15. As a result, a non-conductive portion 17 is formed in the cooling plate 15 by the insertion portion 16a of the non-conductive member 16.

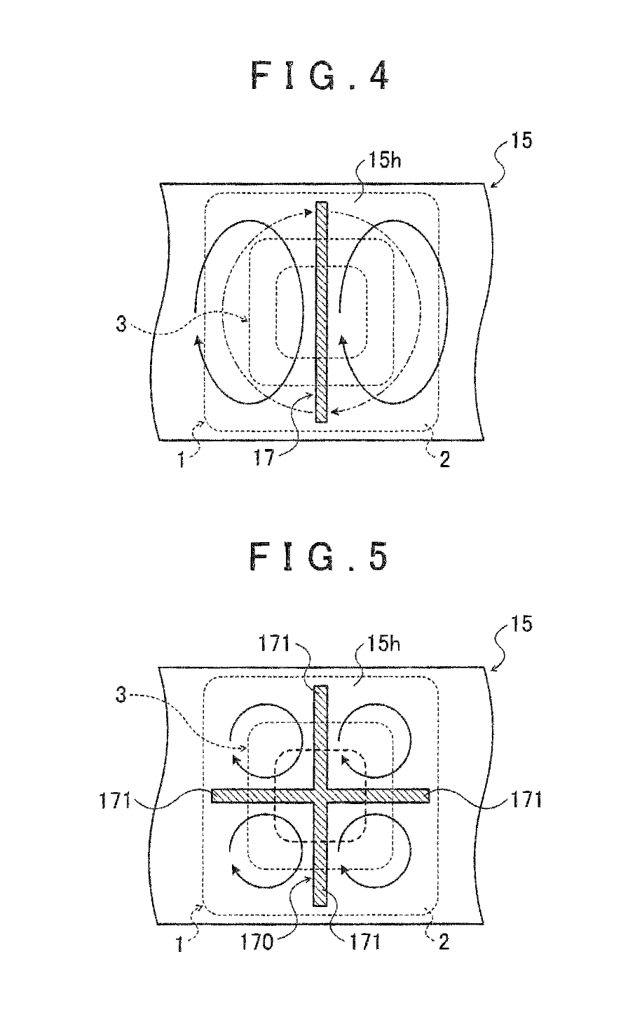

The cooler 10, which is constituted as described above, has the flow passage 12 for cooling water therein and is disposed in contact with the reactor 1 as an electronic component. Thus, heat exchange occurs between the reactor 1 and the cooling water in the flow passage 12 via the heat transfer portion 15h of the cooling plate 15, and the reactor 1 can be therefore cooled efficiently. The heat transfer portion 15h of the cooling plate 15, which constitutes the cooler 10, is provided with the non-conductive portion 17. As indicated by dashed-two dotted lines in FIG. 4, the flow of overcurrent that is caused by the magnetic flux that is generated around (leaks from) the reactor 1 can be blocked or interrupted by the non-conductive portion 17 of the heat transfer portion 15h. Thus, as indicated by solid line arrows in FIG. 4, the overcurrent that is generated in the vicinity of the cooler 10 are reduced and an increase of loss in the reactor 1, in other words, overcurrent loss, can be prevented.

The cooler 10 includes the cooling plate 15 as a first portion that includes the heat transfer portion 15h, and the cooler body 11 as a second portion that is fixed to the cooling plate 15 and defines the flow passage 12 in conjunction with the cooling plate 15. The non-conductive portion 17 is constructed by inserting the insertion portion 16a of the non-conductive member 16 into the slit 15s that is formed through the cooling plate 15. Thus, the non-conductive portion 17 can be easily provided in the heat transfer portion 15h of the cooling plate 15. In addition, the cooler body 11 of the cooler 10 has the wall portion 11b and the protrusions 14. The wall portion 11b is opposed to the heat transfer portion 15h of the cooling plate 15. The protrusions 14 protrude from an inner surface of the wall portion 11b toward the heat transfer portion 15h and are in contact with the base portion 16b of the non-conductive member 16. Thus, when the non-conductive member 16 is assembled to the heat transfer portion 15h of the cooling plate 15, the protrusions 14 of the cooler body 11 can support the non-conductive member 16. As a result, the non-conductive member 16 can be liquid-tightly joined to the cooling plate 15 with ease. The protrusions 14 are arranged at spaced locations along the slit 15s of the cooling plate 15. In other words, the protrusions 14 are arranged at spaced locations (at regular intervals) along the insertion portion 16a of the non-conductive member 16. Thus, the cooler body 11 can stably support the non-conductive member 16 via the protrusions 14 without disrupting the flow of the cooling medium through the flow passage 12.

As described above, according to the cooler 10, it is possible to prevent an increase of loss in the reactor 1 as an electronic component and to cool the reactor 1 efficiently. In addition, the cooler 10 can prevent an increase of loss in the electronic component by reducing the overcurrent that is generated in the vicinity of the cooler 10 by the magnetic flux that is generated around the electronic component. Thus, the cooler 10 is very useful for cooling an electronic component in which loss is increased by overcurrent, such as the reactor 1. It is, however, needless to say that the scope of application of the cooler 10 is not limited to the reactor 1, and the cooler 10 may be applied to another electronic component, such as a capacitor.

In order to improve the cooling efficiency of the cooler 10, fins may be provided on the cooling plate 15 or the cooler body 11. Also, as shown in FIG. 5, a non-conductive portion 170 that has a plurality of overcurrent interrupting portions 171 that extends radially from a position corresponding to the center of the coil 3 may be provided in the heat transfer portion 15h of the cooling plate 15. In this case, the flow of overcurrent that is caused by the magnetic flux that is generated around (leaks from) the reactor 1 can be blocked or interrupted more effectively by the non-conductive portion 170. Thus, the overcurrent that is generated in the vicinity of the cooler 10 can be further reduced and an increase of loss (overcurrent loss) in the reactor 1 can be prevented more efficiently. The non-conductive portion 170 as described above can be realized by forming an opening (slit) (not shown) corresponding in shape to the non-conductive portion 170 through the cooling plate 15, or forming the opening (slit) as described above and preparing a non-conductive member that has an insertion portion (not shown) corresponding in shape to the non-conductive portion 170 and a base portion (not shown) that is formed integrally with the insertion portion so as to be in contact with an inner surface of the cooling plate 15.

Alternatively, a non-conductive member 160 that has a recess (groove) 16c which can receive a seal member 18, such as an O-ring, in the cooling plate 15—side surface of the base portion 16b as shown in FIG, 6 may be applied to the cooler 10 instead of the non-conductive member 16 as described above. A seal member 18 may be provided between the recess 16c of the non-conductive member 160 and the cooling plate 15. In this case, the cooling water can be prevented more reliably from leaking from the flow passage 12 through the slit 15s. The non-conductive member 160 as described above may be joined (welded and fixed) to the cooling plate 15 as in the case of the non-conductive member 16, or may be pressed and placed in position with respect to the cooling plate 15 by the protrusions 14.

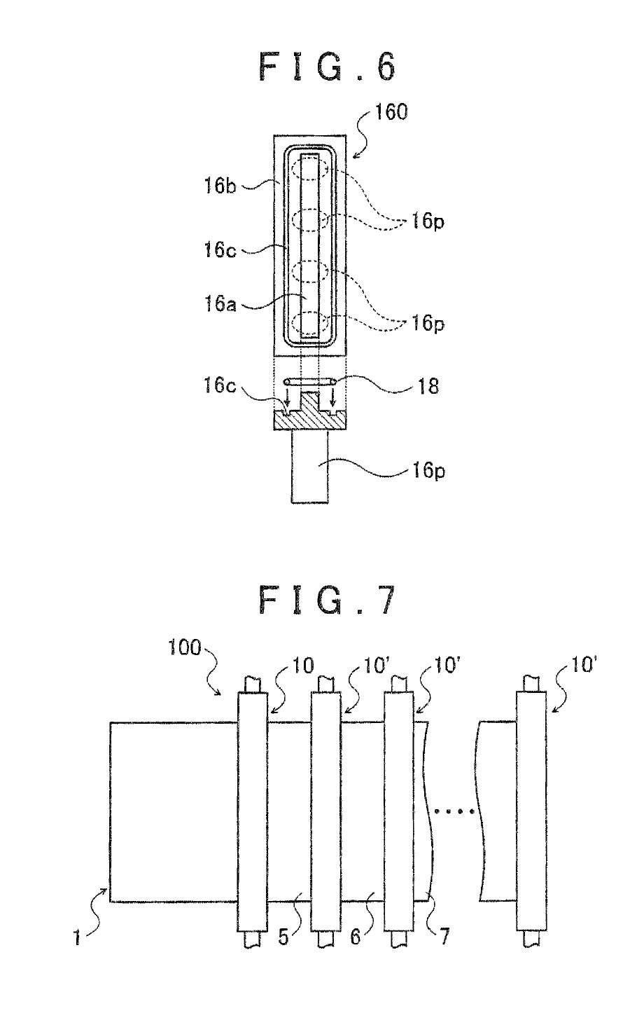

In addition, instead of the protrusions 14 that protrude from an inner surface of the wall portion 11b of the cooler body 11 toward the cooling plate 15, a plurality of protrusions 16p (second protrusions) may protrude from the back side of the base portion 16b as in the case of the non-conductive member 160 that is shown in FIG. 6. In this case, the protrusions 16p are formed to protrude from the back side of the base portion 16b of the non-conductive member 160 toward an inner surface of the wall portion 11b of the cooler body 11 that is opposed to the cooling plate 15. In addition, the base portion 16b is also formed to be in contact with an inner surface of the wall portion 11b. As a result, when the non-conductive member 16 is assembled to the heat transfer portion 15h of the cooling plate 15, the inner surface of the wall portion 11b of the cooler body 11 can support the protrusions 16p of the non-conductive member 16. As a result, the non-conductive member 16 can be liquid-tightly joined to the cooling plate 15 with ease.

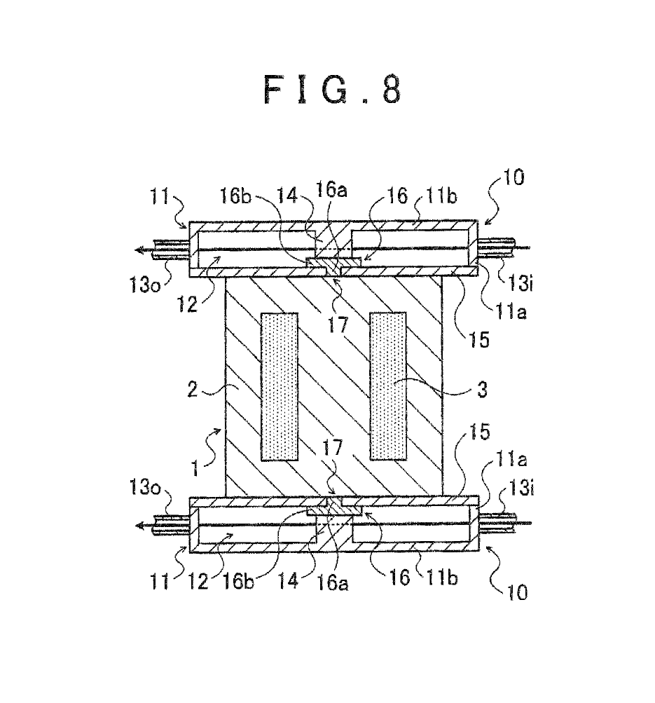

Alternatively, coolers 10′ which are similar in construction to the cooler 10 or are not provided with the non-conductive member 16 may be used in conjunction with the cooler 10 as shown in FIG. 7. In other words, the cooler 10 and the coolers 10′ may be used to construct a stacked cooler 100 that can cool other electronic components 5, 6, 7 . . . such as semiconductor modules in addition to the reactor 1. In this case, the reactor 1 and the cooler 10 are preferably located at a terminal end of the stacked cooler 100 as shown in FIG. 7. As shown in FIG. 8, coolers 10 may be located on both sides of the reactor 1 as an electronic component. When the coolers 10 are located on both sides of the reactor 1 as described above, the reactor 1 can be cooled more efficiently. In addition, the reactor 1 and two coolers 10 can be disposed in the middle of a stacked cooler 100 as shown in FIG. 7.

The above embodiment is merely an example that is used to describe a mode for carrying out the present invention in detail. Thus, the key elements of the above embodiment are not intended to limit the key elements of the invention that is described in SUMMARY OF THE INVENTION. In other words, the embodiment is merely a specific example of the invention that is described in SUMMARY OF THE INVENTION. The interpretation of the invention that is described in SUMMARY OF THE INVENTION should be made based on the description in the section.

While an embodiment of the present invention is described in the foregoing, the present invention is not limited by the above embodiment at all. It is needless to say that various modifications can be made to the present invention without departing from the gist of the present invention.

### INDUSTRIAL APPLICABILITY

The present invention can be utilized in the field of production of a cooler that is used to cool an electronic component.

What is claimed is:

1. A cooler that is disposed in contact with an electronic component to cool the electronic component, the cooler comprising:
a flow passage for a cooling medium that is provided in the cooler;
a heat transfer portion that is in contact with the electronic component and contacts the cooling medium that flows through the flow passage; and
a non-conductive portion that is provided in the heat transfer portion.

2. The cooler according to claim further comprising:
a first portion that includes the heat transfer portion, the heat transfer portion of the first portion having an opening; and
a second portion that is fixed to the first portion, the second portion defining the flow passage in conjunction with the first portion;
wherein the non-conductive portion is constituted of a non-conductive member that is disposed in the opening.

3. The cooler according to claim 2, wherein
the second portion has a wall portion that is opposed to the heat transfer portion of the first portion, and at least one first protrusion that protrudes from the wall portion toward the heat transfer portion and is in contact with the non-conductive member.

4. The cooler according to claim 3, wherein
the second portion has a plurality of the first protrusions, the first protrusions being arranged at intervals along the opening.

5. The cooler according to claim 2, wherein
the non-conductive member has at least one second protrusion, the second protrusion protruding toward a wall portion of the second portion that is opposed to the heat transfer portion of the first portion and being in contact with the wall portion.

6. The cooler according to claim 5, wherein
the non-conductive member has a plurality of the second protrusions, the second protrusions being arranged at intervals along the opening.

7. The cooler according to claim 1, wherein
the electronic component is a reactor.
